(19) United States
(12) Patent Application Publication
(10) Pub. No.: US 2025/0221173 A1
(43) Pub. Date: Jul. 3, 2025

(54) DISPLAY PANEL AND METHOD OF MANUFACTURING THE SAME

(71) Applicant: HKC CORPORATION LIMITED, SHENZHEN (CN)

(72) Inventors: Yangling TANG, SHENZHEN (CN); Qin LIANG, SHENZHEN (CN); Xiufeng ZHOU, SHENZHEN (CN); Lidan YE, SHENZHEN (CN)

(73) Assignee: HKC CORPORATION LIMITED, SHENZHEN (CN)

(21) Appl. No.: 18/991,351

(22) Filed: Dec. 21, 2024

(30) Foreign Application Priority Data
Dec. 27, 2023 (CN) 202311833373.2

(51) Int. Cl. H10K 59/122; H10K 59/12

(52) U.S. Cl. CPC H10K 59/122; H10K 59/1201

(57) ABSTRACT

A display panel includes: a substrate, a pixel defining layer, sub-pixels, and an isolation structure. The pixel defining layer is arranged on a side of the substrate and has pixel openings. Each sub-pixel is arranged in one pixel opening. Each sub-pixel comprises an anode, a light emitting layer and a cathode. The isolation structure surrounds the pixel opening and is electrically connected to the sub-pixel in the pixel opening surrounded by the isolation structure. The light emitting layer and the cathode of the sub-pixel are vapor-deposited sequentially on a surface of the anode. A difference between a vapor-deposition angle of a vapor-deposition material forming the light emitting layer or the cathode in a second direction and a vapor-deposition angle of the vapor-deposition material in a first direction is greater than 10 degrees and less than 40 degrees; and the first and the second directions are perpendicular to each other.

### CROSS REFERENCE TO RELATED APPLICATIONS

The present application claims the priority of the Chinese patent application No. 202311833373.2, filed on Dec. 27, 2023, and contents of which are incorporated herein by its entireties.

### TECHNICAL FIELD

The present disclosure relates to the field of displaying, and in particular to a display panel and a method of manufacturing a display panel.

### BACKGROUND

In the art, organic light-emitting diodes (OLEDs) are prepared by performing vapor deposition using fine reticles. The reticle is expensive, and therefore, developing new products may be costly. In addition, a bridging region at an opening of the fine reticle limits an effective area of vapor deposition of a pixel light-emitting region, such that an opening ratio cannot be improved.

### SUMMARY OF THE DISCLOSURE

The present disclosure provides a display panel and a method of manufacturing a display panel, such that the pixel opening ratio of the display panel may be increased.

In a first aspect, the present disclosure provides a display panel, including:
a substrate;
a pixel defining layer, arranged on a side of the substrate and having a plurality of pixel openings that are spaced apart from each other;
a plurality of sub-pixels, wherein each of the plurality of sub-pixels is arranged in a respective one of the plurality of pixel openings; each of the plurality of sub-pixels comprises an anode, a light emitting layer and a cathode that are arranged sequentially in a direction away from the substrate;
an isolation structure, protruding from the pixel defining layer and surrounding at least one of the plurality of pixel openings; wherein, the isolation structure is electrically connected to a respective one of the plurality of sub-pixels arranged in the respective pixel opening surrounded by the isolation structure.

The light emitting layer and the cathode of the sub-pixel are vapor-deposited sequentially on an upper surface of the anode; a difference between a vapor-deposition angle of a vapor-deposition material forming the light emitting layer or the cathode in a second direction and a vapor-deposition angle of the vapor-deposition material in a first direction is greater than 10 degrees and less than 40 degrees; and the first and the second directions are perpendicular to each other and are parallel to the substrate.

In a second aspect, the present disclosure provides a method of manufacturing the display panel as described in the above. The method includes:
providing a substrate and preparing a plurality of anodes of the plurality of sub-pixels on a side of the substrate;
forming a patterned pixel defining layer on the substrate, wherein, the pixel defining layer has the plurality of pixel openings that are spaced apart from each other, each of the plurality of pixel openings exposes at least a portion of a respective one of the plurality of anodes;
preparing the isolation structure, wherein, the isolation structure is protruding from the pixel defining layer and surrounds the respective one of the plurality of pixel openings;
sequentially vapor-depositing the light emitting layer of each sub-pixel and the cathode of each sub-pixel in the respective pixel opening; wherein, each of the plurality of sub-pixels is received in a respective one of the plurality of pixel openings; the isolation structure is electrically connected to the respective sub-pixel arranged in the respective pixel opening surrounded by the isolation structure;

The difference between the vapor-deposition angle of the vapor-deposition material forming the light emitting layer or the cathode in the second direction and the vapor-deposition angle of the vapor-deposition material in the first direction is greater than 10 degrees and less than 40 degrees; wherein the first direction and the second direction are perpendicular to each other and are parallel to the substrate.

According to the present disclosure, a display panel and a method for manufacturing a display panel are provided. The display panel includes a substrate, a pixel defining layer, a plurality of sub-pixels, and an isolation structure. The pixel defining layer is arranged on a side of the substrate and has a plurality of pixel openings, the plurality of pixel openings are spaced apart from each other. Each of the plurality of sub-pixels is disposed in a respective one of the plurality of pixel openings. Each sub-pixel includes an anode, a light emitting layer, and a cathode, that are sequentially arranged in a direction away from the substrate. The isolation structure is protruding from the pixel defining layer and surrounds the pixel openings. The isolation structure is electrically connected to the sub-pixel arranged in the pixel opening that is surrounded by the isolation structure. The light emitting layer and the cathode of the sub-pixel are sequentially vapor-deposited on an upper surface of the anode. For the vapor-deposition material forming the light emitting layer or the cathode, a difference between a vapor-deposition angle of the vapor-deposition material in a second direction and a vapor-deposition angle of the vapor-deposition material in a first direction is greater than 10 degrees and less than 40 degrees. The first direction and the second direction are perpendicular to each other and are parallel to the substrate. In the present disclosure, when vapor-depositing the light emitting layer or the cathode of the sub-pixel, the vapor-deposition angle of the same vapor-deposition material in the second direction and/or the vapor-deposition angle of the same vapor-deposition material in the first direction is adjusted. In this way, a distance between an edge of the isolation structure and an edge of an end of a pixel opening away from the substrate can be adjusted, where the pixel opening is surrounded by and adjacent to the isolation structure. Therefore, a distance between the sub-pixel and the isolation structure is adjusted, and the pixel opening ratio is increased.

### BRIEF DESCRIPTION OF THE DRAWINGS

In order to more clearly illustrate the technical solutions in the embodiments of the present disclosure, the accompanying drawings for describing the embodiments will be briefly introduced in the following. Obviously, the accompanying drawings in the following show only some of the embodiments of the present disclosure, and any ordinary skilled person in the art may obtain other accompanying drawings based on the following drawings without any creative work.

FIG. 1 is a structural schematic view of a vapor-deposition source and a limiting board of an embodiment in the art.

FIG. 2 is a structural schematic view of a display panel according to a first embodiment of the present disclosure.

FIG. 3 is a cross-sectional view of the display panel shown in FIG. 2, taken along a line E-E.

FIG. 4 is a cross-sectional view of the display panel shown in FIG. 2, taken along a line F-F.

FIG. 5 is a structural schematic view of a display panel according to a second embodiment of the present disclosure.

FIG. 6 is a structural schematic view of a display panel according to a third embodiment of the present disclosure.

FIG. 7 is a structural schematic view of a display panel according to a fourth embodiment of the present disclosure.

FIG. 8 is a structural schematic view of a sub-pixel according to an embodiment of the present disclosure.

FIG. 9 is a flow chart of a method of manufacturing the display panel according to an embodiment of the present disclosure.

FIG. 10 is a structural schematic view of structures corresponding to operations S10 to S40 in FIG. 9.

### REFERENCE NUMERALS IN THE DRAWINGS

10, substrate; 20, pixel defining layer; 21, pixel opening; 30, sub-pixel; 30A, first sub-pixel; 30B, second sub-pixel; 30C, third sub-pixel; 31, anode; 32, light emitting layer; 33, cathode; 40, pixel unit; 50, isolation structure; 51, conductive portion; 52, insulation portion; X, first direction; Y, second direction; a1, first spacing; a2, second spacing; b1, first width; b2, second width; d/a1′/a2′, spacing; θ1/θ2, vapor-deposition angle; 100, vapor-deposition source; 200, limiting board.

### DETAILED DESCRIPTION

Technical solutions of embodiments of the present disclosure will be described in detail by referring to the accompanying drawings of the specification.

In the following description, specific details, such as particular system structures, interfaces, techniques, and the like, are presented for the purpose of illustration and not for limiting the present disclosure, sch that the present disclosure may be understood thoroughly.

The technical solutions in the embodiments of the present disclosure are described clearly and completely in the following by referring to the accompanying drawings in the embodiments of the present disclosure. Obviously, the described embodiments show only a part of, not all of, the embodiments of the present disclosure. All other embodiments, which are obtained by any ordinary skilled person in the art based on the embodiments of the present disclosure without making creative work, shall fall within the scope of the present disclosure.

Terms “first”, “second”, and “third” in the present disclosure are used for descriptive purposes only and shall not be interpreted as indicating or implying relative importance or implicitly specifying the number of indicated technical features. Therefore, a feature defined by the “first”, the “second”, the “third” may include at least one such features, either explicitly or implicitly. In the description of the present disclosure, “plurality” means at least two, such as two, three, and so on, unless otherwise expressly and specifically limited. All directional indications (such as up, down, left, right, front, rear . . . ) in embodiments of the present disclosure are used only to explain relative positional relationships and movements between components in a particular attitude (the attitude shown in the accompanying drawings). When the particular attitude changes, the directional indications may change accordingly. Furthermore, terms “include” and “have” and any variations thereof are intended to cover non-exclusive inclusion. For example, a process, a method, a system, a product or an apparatus including a series of steps or units is not limited to the listed steps or units, but may further include steps or units that are not listed or include other steps or units that are inherently included in the process, the method, the system, the product or the apparatus.

The term “embodiment” herein implies that particular features, structures, or properties described in an embodiment may be included in at least one embodiment of the present disclosure. The presence of the term at various sections in the specification does not necessarily refer to a same embodiment, nor a separate or an alternative embodiment that is mutually exclusive of other embodiments. Any ordinary skilled person in the art may understand that, both explicitly and implicitly, the embodiments described herein may be combined with other embodiments.

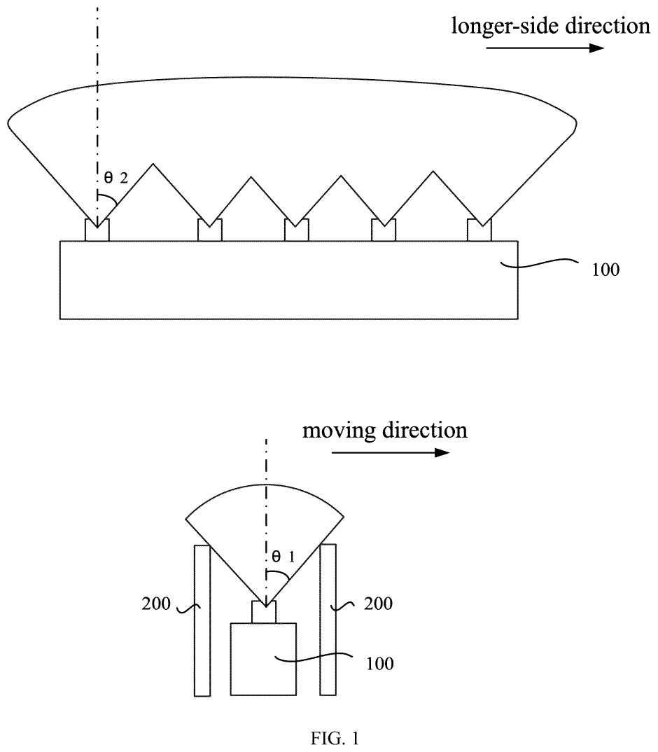

As shown in FIG. 1, FIG. 1 is a structural schematic view of a vapor-deposition source and a limiting board of an embodiment in the art.

In the art, for a vapor-deposition process in practice, a vapor-deposition source 100 generates a piece of vapor-deposition cloud along a longer-side direction of the vapor-deposition source 100, and no limiting board 200 is arranged to restrict an angle. Therefore, a vapor-deposition angle θ2 of the vapor-deposition material in the longer-side direction is relatively large. In a moving direction of the vapor-deposition source 100, limiting boards 200 on two sides of the vapor-deposition source 100 can control a vapor-deposition angle θ1. Furthermore, the vapor-deposition angle θ2 of the vapor-deposition material in the longer-side direction is larger than the vapor-deposition angle θ1 of the vapor-deposition material in the moving direction.

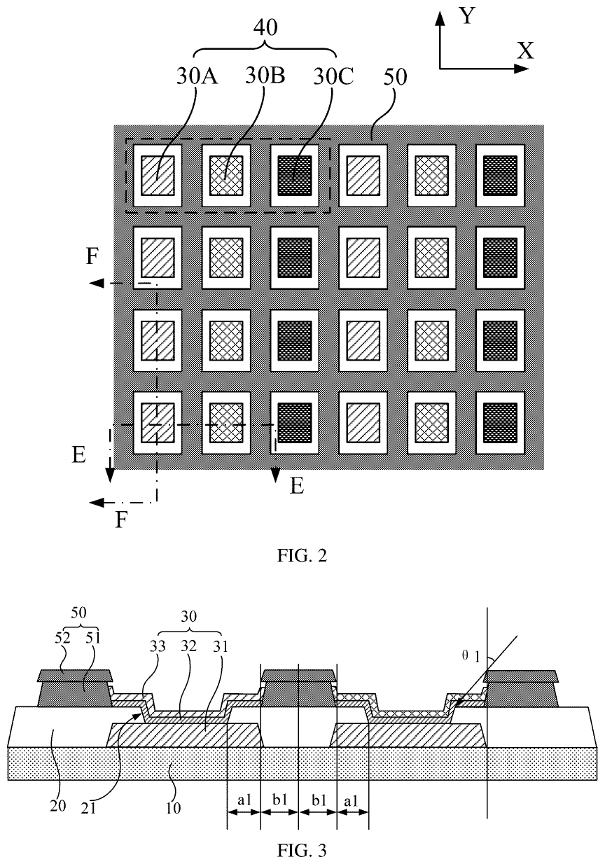

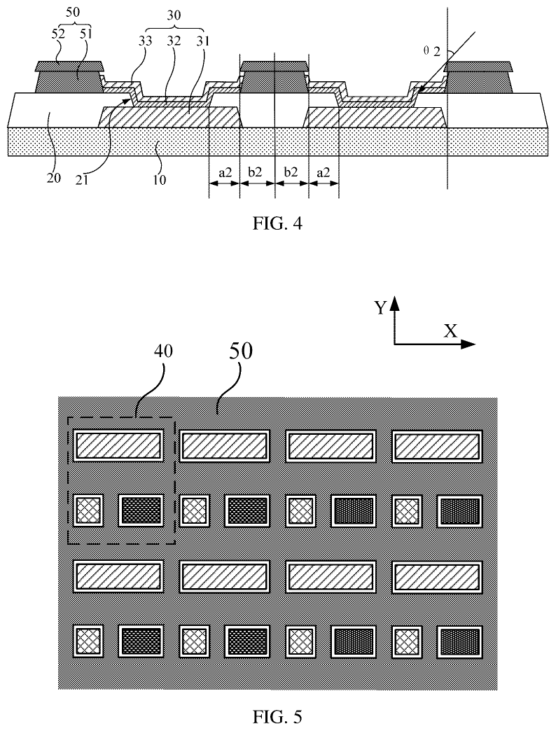

As shown in FIG. 2 to FIG. 4, FIG. 2 is a structural schematic view of a display panel according to a first embodiment of the present disclosure; FIG. 3 is a cross-sectional view of the display panel shown in FIG. 2, taken along a line E-E; and FIG. 4 is a cross-sectional view of the display panel shown in FIG. 2, taken along a line F-F.

According to the above principles, the present disclosure provides a display panel including a substrate 10, a pixel defining layer 20, a plurality of sub-pixels 30, and an isolation structure 50. The pixel defining layer 20 is arranged on a side of the substrate 10 and has a plurality of pixel openings 21, the plurality of pixel openings 21 are spaced apart from each other. Each of the plurality of sub-pixels 30 is disposed in a respective one of the plurality of pixel openings 21. Each sub-pixel 30 includes an anode 31, a light emitting layer 32 and a cathode 33 that are sequentially arranged in a direction away from the substrate 10. The isolation structure 50 is protruding from the pixel defining layer 20 and surrounds each pixel opening 21. The isolation structure 50 is electrically connected to the sub-pixel 30 disposed in the pixel opening 21 surrounded by the isolation structure 50. The light emitting layer 32 and the cathode 33 of the sub-pixel 30 are sequentially vapor-deposited on an upper surface of the anode 31. For a vapor-deposition material forming the light emitting layer 32 or the cathode 33, a difference between a vapor-deposition angle θ2 of the vapor-deposition material in a second direction Y and a vapor-deposition angle θ1 of the vapor-deposition material in a first direction X is greater than 10 degrees and less than 40 degrees. The first direction X and the second direction Y are perpendicular to each other and are both parallel to the substrate 10.

In the present disclosure, when the light emitting layer 32 or the cathode 33 of the sub-pixel 30 is being vapor-deposited, the vapor-deposition angle θ2 of the vapor-deposition material in the second direction Y and/or the vapor-deposition angle θ1 of the vapor-deposition material in the first direction X is adjusted, such that a spacing between an edge of the isolation structure 50 and an edge of an end of the pixel opening 21 away from the substrate 10 is adjusted, where the pixel opening 21 is surrounded by the isolation structure 50 and is adjacent to the isolation structure 50. In this way, a spacing between the sub-pixel 30 and the isolation structure 50 is adjusted, the pixel opening ratio is increased.

A material and a thickness of the substrate 10 are not limited herein and can be determined according to demands.

The pixel defining layer 20 defines positions of the sub-pixels 30. A material and a thickness of the pixel defining layer 20 are limited herein and can be determined according to demands. A shape of an outer contour of the end of the pixel opening 21 away from the substrate 10 determines a shape of the sub-pixel 30 received in the pixel opening.

One sub-pixel 30 corresponds to one pixel opening 21. One sub-pixel 30 corresponds to one color. The color corresponding to the sub-pixel 30 is not limited herein and can be determined according to demands.

The sub-pixel 30 includes the anode 31, the light emitting layer 32, and the cathode 33 that are sequentially arranged in the direction away from the substrate 10. The anode 31 is disposed between the substrate 10 and the pixel defining layer 20. The pixel opening 21 exposes at least a portion of the anode 31 to enable the light emitting layer 32 to be in contact with the anode 31 through the pixel opening 21.

In the present embodiment, the pixel opening 21 exposes a portion of the anode 31. Materials of the anode 31, the light-emitting layer 32 and the cathode 33, and a method of manufacturing the anode 31 are not limited herein and can be determined according to demands. The light emitting layer 32 and the cathode 33 of the sub-pixel 30 are sequentially vapor-deposited on the upper surface of the anode 31 by a vapor-deposition source.

Specifically, the sub-pixel 30 includes an organic light-emitting diode (OLED).

The isolation structure 50 is arranged on an upper surface of the pixel defining layer 20 and is protruding from the pixel defining layer 20 in a direction perpendicular to the substrate 10. The isolation structure 50 surrounds at least one of the plurality of pixel openings 21.

To be noted that the upper surface in the present application refers to a side surface away from the substrate 10.

The present embodiment is illustrated by taking one isolation structure 50 surrounding one pixel opening 21 as an example. In a direction parallel to the substrate 10, a shape of a region surrounded by the isolation structure 50 is similar to a shape of the sub-pixel. Each side wall of the isolation structure 50 corresponds to and is parallel with a respective side edge of the sub-pixel 30 surrounded by the isolation structure 50 That is, the side edge of the sub-pixel 30 is parallel with the side wall, which is adjacent to the sub-pixel 30, of the isolation structure 50.

In other embodiments, one isolation structure 50 may surround more than one of the plurality of pixel openings 21. More than one sub-pixels 30 received in the more than one pixel openings 21 surrounded by the one isolation structure 50 correspond to a same color, such that pixel crosstalk is avoided.

The isolation structure 50 includes a conductive portion 51 and an insulation portion 52 arranged on an upper surface of the conductive portion 51. The insulation portion 52 shields the conductive portion 51 and extends out of the conductive portion 51 in a direction parallel to the substrate 10. The conductive portion 51 is electrically connected to the cathode 33 of the sub-pixel 30 received in the pixel opening 21 surrounded by the isolation structure 50. That is, an orthographic projection area of the isolation portion 52 on the substrate 10 is larger than an orthographic projection area of the conductive portion 51 on the substrate 10, and the orthographic projection area of the insulation portion 52 on the substrate 10 covers the orthographic projection area of the conductive portion 51 on the substrate 10. Electrical connection between the cathode 33 of the sub-pixel 30 and the isolation structure 50 is achieved by the cathode 33 of the sub-pixel 30 being electrically connected to the conductive portion 51 of the isolation structure 50. When the light emitting layer 32 or the cathode 33 of the sub-pixel 30 is being vapor-deposited, the vapor-deposition angle is adjusted by an edge of the insulation portion 52. That is, the isolation structure 50 can isolate the sub-pixel 30 and allows cathodes 33 of the plurality of sub-pixels of a layer to be connected to each other to form a mesh, facilitating the cathodes 33 of the plurality of sub-pixels to be homogenous.

The isolation structure 50 may be other structures, which are not limited herein and can be determined according to demands. The edge of the isolation structure 50 has a pointing direction that points towards the edge of the end of the pixel opening 21 near the substrate 10, where the pixel opening 21 is surrounded by and adjacent to the isolation structure 50. An angle between the pointing direction and a direction perpendicular to the substrate 10 is the vapor-deposition angle of the vapor-deposition material. That is, when one isolation structure 50 surrounds the more than one pixel openings 21, the pixel opening 21 that has the defined vapor-deposition angle of the vapor-deposition material must be adjacent to the isolation structure 50, and the pixel opening 21 is surrounded by the isolation structure 50. When one isolation structure 50 surrounds one sub-pixel 30, the edge of the isolation structure 50 has the pointing direction that points towards the edge of the end of the pixel opening 21 near the substrate 10, where the pixel opening 21 is surrounded by and adjacent to the isolation structure 50. The angle between the pointing direction and the direction perpendicular to the substrate 10 is the vapor-deposition angle of the vapor-deposition material.

The vapor-deposition angle of the vapor-deposition material is also referred to as a deposition angle of the vapor-deposition material. The vapor-deposition angle is less than 90 degrees.

The first direction X is a moving direction of the vapor-deposition source, and the second direction Y is the longer-side direction of the vapor-deposition source.

The vapor-deposition material is a material forming the light emitting layer 32 of the sub-pixel 30 or the cathode 33 of the sub-pixel 30. To be noted that, in the present disclosure, the difference between the vapor-deposition angle θ2 of the vapor-deposition material in the second direction Y and the vapor-deposition angle θ1 of the vapor-deposition material in the first direction X refers to a difference between vapor-deposition angles of a same vapor-deposition material in two different directions. The same vapor-deposition material refers to a material forming cathodes 33 or light emitting layers 32 of sub-pixels 30 in a same color. Furthermore, the same vapor-deposition material may alternatively be referred to as a vapor-deposition material that is ejected from the same vapor-deposition source when the light emitting layers 32 or the cathodes 33 of the sub-pixels 30 in the same color are being vapor-deposited.

Specifically, the above angle different can be interpreted as a difference between the vapor-deposition angle θ2 of the vapor-deposition material ejected by the vapor-deposition source in the second direction Y and the vapor-deposition angle θ1 of the vapor-deposition material ejected by the vaporizing source in the first direction X, when the light emitting layers 32 of the sub-pixels 30 in the same color are being vapor-deposited. Further, the above angle different can be interpreted as a difference between the vapor-deposition angle θ2 of the vapor-deposition material ejected by the vapor-deposition source in the second direction Y and the vapor-deposition angle θ1 of the vapor-deposition material ejected by the vaporizing source in the first direction X, when the cathodes 32 of the sub-pixels 30 in the same color are being vapor-deposited.

For the vapor-deposition material forming the light-emitting layer 32 or the cathode 33, the difference between the vapor-deposition angle θ2 of the vapor-deposition material in the second direction Y and the vapor-deposition angle θ1 of the vapor-deposition material in the first direction X is greater than 10 degrees and less than 40 degrees. In this way, in a process of vapor-depositing the sub-pixel 30, the cathode 33 of the sub-pixel 30 covers the light emitting layer 32 of the sub-pixel 30. In addition, the conductive portion 51 of the isolation structure 50 is lapped properly, and in this case, the vapor-deposition angle θ2 of the same vapor-deposition material in the second direction Y and/or the vapor-deposition angle θ1 of the same vapor-deposition material in the first direction X is adjusted, such that the spacing between the edge of the isolation structure 50 and the edge of the end of the pixel opening 21 away from the substrate 10 is adjusted, where vapor-deposition is surrounded by and is adjacent to the isolation structure 50. Therefore, the spacing between the isolation structure 50 and the surrounded sub-pixel 30 is adjusted, and the pixel opening ratio is increased.

To be noted that “A and/or B” in the present disclosure indicates that only A is included, or only B is included, or both A and B are included.

In an embodiment, the difference between the vapor-deposition angle θ2 of the vapor-deposition material in the second direction Y and the vapor-deposition angle θ1 of the same vapor-deposition material in the first direction X is greater than 15 degrees and less than 30 degrees. For example, the difference between the vapor-deposition angle θ2 of the vapor-deposition material in the second direction Y and the vapor-deposition angle θ1 of the same vapor-deposition material in the first direction X may be 16 degrees, 18 degrees, 20 degrees, 22 degrees, 24 degrees, 26 degrees, 28 degrees, and 29 degrees.

Specifically, in the present disclosure, while it is ensured that the cathode 33 is properly lapped to the conductive portion 51, the vapor-deposition angle θ2 of the same vapor-deposition material in the second direction Y and/or the vapor-deposition angle θ1 of the same vapor-deposition material in the first direction X is adjusted, such that the spacing, in the second direction Y, between the edge of the isolation structure 50 and the edge of the end of the pixel opening 21 away from the substrate 10 is reduced, where the pixel opening 21 is surrounded by and adjacent to the isolation structure 50; furthermore/alternatively, the spacing, in the first direction X, between the edge of the isolation structure 50 and the edge of the end of the pixel opening 21 away from the substrate 10 is reduced. That is, the spacing, in the first direction X and/or the second direction Y, between the isolation structure 50 and the pixel opening 21 surrounded by and adjacent to the isolation structure 50 is reduced. In this way, the pixel opening ratio is increased.

It is understood that when the difference between the vapor-deposition angle θ2 of the vapor-deposition material in the second direction Y and the vapor-deposition angle θ1 of the same vapor-deposition material in the first direction X is excessively small or large, the pixel opening ratio may not be increased ideally.

In an embodiment, in the direction perpendicular to the substrate 10, a distance between the upper surface of the anode 31 and the upper surface of the isolation structure 50 is 1.3 μm to 2 μm. The distance value ensures that the sub-pixel 30 can be properly vapor-deposited and isolated, and the vapor-deposition angle of the vapor-deposition material can be adjusted easily.

It is understood that, in the direction perpendicular to the substrate 10, when the distance between the upper surface of the anode 31 and the upper surface of the isolation structure 50 is excessively small, the sub-pixel 30 may not be isolated properly. In the direction perpendicular to the substrate 10, when the distance between the upper surface of the anode 31 and the upper surface of the isolation structure 50 is excessively large, materials may be wasted.

In the present disclosure, in the first direction X, the spacing from the edge of the isolation structure 50 and the edge of the end of the pixel opening 21 away from the substrate 10 is a first spacing a1, where the pixel opening 21 is surrounded by and adjacent to the isolation structure 50; and a half of a width of the side wall of the isolation structure 50 is a first width b1. In the second direction Y, the spacing from the edge of the isolation structure 50 and the edge of the end of the pixel opening 21 away from the substrate 10 is a second spacing a2, where the pixel opening 21 is surrounded by and adjacent to the isolation structure 50; and a half of a width of the side wall of the isolation structure 50 is a second width b2.

To be noted that, in the first direction X, for side walls of the plurality of isolation structures 50 extending in a same direction, edges of the side walls of the plurality of isolation structures 50 have a same spacing to respective edges of ends of the plurality of pixel openings away from the substrate 10, where the respective pixel openings are surrounded by and adjacent to the respective isolation structures 50. In this way, it is ensured that the vapor-deposition material may be arranged to have a same vapor-deposition angle in the first direction X to vapor-deposit the light emitting layers 32 or the cathodes 33 of the sub-pixels 30. Further, in the second direction Y, for side walls of the plurality of isolation structures 50 extending in a same direction, edges of the side walls of the plurality of isolation structures 50 have a same spacing to respective edges of ends of the plurality of pixel openings away from the substrate 10, where the respective pixel openings are surrounded by and adjacent to the respective isolation structures 50. In this way, it is ensured that the vapor-deposition material may be arranged to have a same vapor-deposition angle in the second direction Y to vapor-deposit the light emitting layers 32 or the cathodes 33 of the sub-pixels 30. In this way, manufacturing of the sub-pixels 30 can be simplified.

In the present disclosure, in a direction parallel to a plane of the substrate 10, the isolation structure 50 is symmetrically configured along the first direction X and is symmetrically configured along the second direction Y, facilitating manufacturing of the isolation structure 50 when the display panel is being manufactured in practice.

In other embodiments, the isolation structure 50 may be an asymmetric structure.

Further, a difference between the second spacing a2 and the first spacing a1 is greater than or equal to 0.75 μm, and/or an absolute difference value between the first width b1 and the second width b2 is greater than or equal to 0.75 μm. That is, while it is ensured that a size of the isolation structure 50 is unchanged, the difference between the vapor-deposition angle θ2 of the vapor-deposition material forming the light emitting layer 32 or the cathode 33 in the second direction Y and the vapor-deposition angle θ1 of the vapor-deposition material in the first direction X is adjusted, such that the difference between the first spacing a1 and the second spacing a2 is adjusted. In this way, a spacing, in the first direction X or the second direction Y, between edges of two adjacent pixel openings 21 at ends near the substrate 10 is adjusted, such that the pixel opening ratio is increased. Furthermore/alternatively, while it is ensured that the pixel opening ratio remains constant in the first direction X or the second direction Y, the difference between the vapor-deposition angle θ2 of the vapor-deposition material forming the light emitting layer 32 or the cathode 33 in the second direction Y and the vapor-deposition angle θ1 of the vapor-deposition material in the first direction X is adjusted, and the absolute difference value between the first width b1 and the second width b2 is adjusted, such that a width of the isolation structure 50 in the first direction X and/or in the second direction Y is increased. In this way, an impedance of the conductive portion 51 in the isolation structure 50 is reduced, a connection resistance between the cathodes 33 of the sub-pixels 30 is reduced, such that signaling loads of the cathodes 33 are reduced, and displaying uniformity is improved.

To be noted that, in the present disclosure, increasing the width of the isolation structure 50 in the first direction X and/or the second direction Y refers to both a width of the conductive portion 51 and the insulation portion 52 of the isolation structure 50 being increased. That is, the width of the isolation structure 50 in overall is increased in the first direction X and/or the second direction Y in a uniform proportion.

In the present embodiment, the sub-pixel 30 includes a side edge extending along the first direction X and a side edge extending along the second direction Y Specifically, the sub-pixel 30 is rectangular. The display panel further includes a plurality of pixel units 40. Each pixel units 40 includes sub-pixels 30 in three different colors. The sub-pixels 30 in the three different colors are a first sub-pixel 30A, a second sub-pixel 30B, and a third sub-pixel 30C. For every two adjacent sub-pixels 30 of the sub-pixels 30 in the three different colors, each one of the two adjacent sub-pixels 30 has a side disposed close to the other one of the two adjacent sub-pixels, and the closely-disposed sides are parallel to each other. In each pixel unit 40, the first sub-pixel 30A, the second sub-pixel 30B, and the third sub-pixel 30C are disposed sequentially along the first direction X. In the first direction X, a spacing between edges of ends of two adjacent pixel openings 21 near the substrate 10 is equal to two times of a sum of the first width b1 and the first spacing a1. In the second direction Y, the spacing between the edges of the ends of the two adjacent pixel openings 21 near the substrate 10 is equal to two times of a sum of the second width b2 and the second spacing a2.

As shown in FIG. 2 and FIG. 5, FIG. 5 is a structural schematic view of a display panel according to a second embodiment of the present disclosure.

In other embodiments, in each pixel unit 40, the first sub-pixel 30A, the second sub-pixel 30B, and the third sub-pixel 30C may be arranged in a triangular pattern or may be arranged in other manners. The plurality of sub-pixels 30 may be arranged in other shapes or in other manners. Each pixel unit 40 may include sub-pixels 30 of more colors and more sub-pixels, and more than one sub-pixels 30 may be in one color.

To be noted that, in the present disclosure, the spacing, in the first direction X and/or the second direction Y, between each isolation structure 50 and the respective pixel opening 21 surrounded by and adjacent to the isolation structure 50 is designed (i.e., the first spacing a1 and the second spacing a2 are designed) to improve the pixel opening ratio of the sub-pixel 30 received in the respective pixel opening 21 surrounded by the isolation structure 50. That is, on the basis of the arrangement of the sub-pixels 30 in the art, the difference between the vapor-deposition angle θ2 of the vapor-deposition material forming the light emitting layer 32 or the cathode 33 in the second direction Y and the vapor-deposition angle θ1 of the same vapor-deposition material in the first direction X is adjusted in the present disclosure to increase the pixel opening ratio.

That is, compared to arranging the sub-pixels 30 in other manners, the sub-pixels 30 having the shape and the arrangement in the present embodiment may have a maximized pixel opening ratio compared to those in the art.

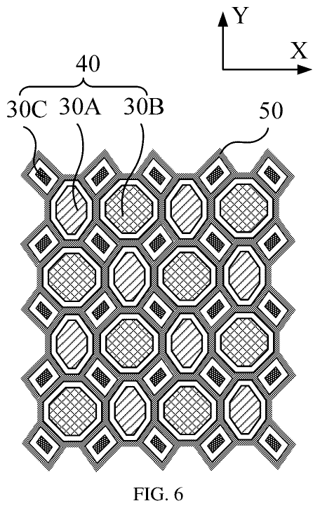

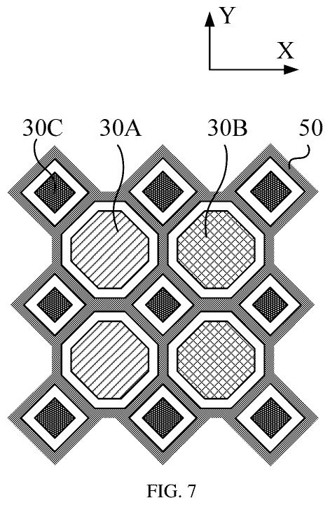

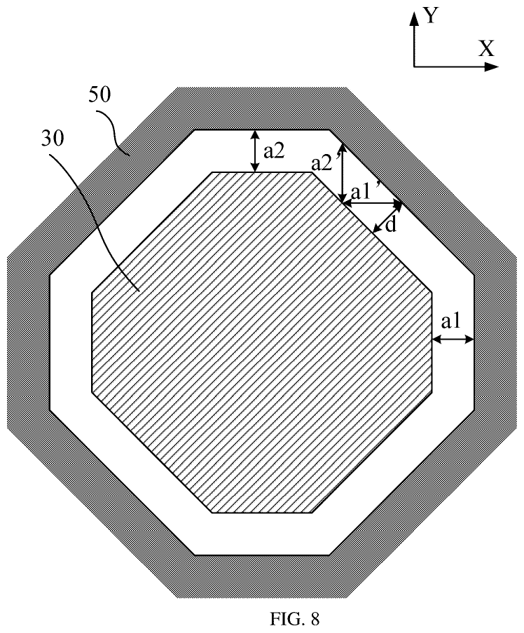

As shown in FIG. 3 to FIG. 8, FIG. 6 is a structural schematic view of a display panel according to a third embodiment of the present disclosure; FIG. 7 is a structural schematic view of a display panel according to a fourth embodiment of the present disclosure; and FIG. 8 is a structural schematic view of the sub-pixel according to an embodiment of the present disclosure.

The display panel in the third embodiment of the present disclosure has essentially the same structure as the display panel in the first embodiment. Furthermore, the sub-pixel 30 includes at least an inclined side.

In some embodiments, the sub-pixel 30 includes at least the inclined side. A portion of the plurality of sub-pixels 30 further include: a side extending along the first direction X and/or a side extending along the second direction Y That is, not all of the plurality of sub-pixels 30 include only the inclined side. The respective isolation structure 50 has an inclined side wall parallel to the inclined side of the respective sub-pixel 30, and not all isolation structures 50 include only the inclined side wall.

An extending direction of the inclined side, the first direction X and the second direction Y are located in a same plane. An angle between the extending direction of the inclined side and the first direction X is 30 degrees to 60 degrees, or an angle between the extending direction of the inclined side and the second direction Y is 30 degrees to 60 degrees.

In the present embodiment, one isolation structure 50 surrounds one pixel opening 21. Each of the first sub-pixel 30A and the second sub-pixel 30B is octagonal. A shape of octagonal is centrally symmetrical. The third sub-pixel 30C is parallelogram. The first sub-pixels 30A and the second sub-pixels 30B are disposed sequentially and alternately in the first direction X and the second direction Y.

Four third sub-pixels 30C surround one first sub-pixel 30A and are symmetrically arranged about the first direction X and the second direction Y, respectively. Four third sub-pixels 30C surround the second sub-pixel 30B and are symmetrically arranged about the first direction X and the second direction Y, respectively.

Specifically, each of the first sub-pixel 30A and the second sub-pixel 30B includes a side extending along the first direction X and a side extending along the second direction Y The four third sub-pixels 30C surrounding the first sub-pixel 30A are disposed corresponding to the inclined sides of the first sub-pixel 30A. The four third sub-pixels 30C surrounding the second sub-pixel 30B are disposed corresponding to the inclined side edges of the second sub-pixel 30B.

In other embodiments, as shown in FIG. 8, when the angle between the extending direction of the inclined side in the first direction X or the angle between the extending direction of the inclined side in the second direction Y is 45 degrees, the third sub-pixel 30C is rectangular. When the first sub-pixel 30A and the second sub-pixel 30B have a same shape and a same size, the first sub-pixels 30A may be repeatedly arranged in the second direction Y, and the second sub-pixels 30B may be repeatedly arranged in the second direction Y.

A difference between a first spacing a1 from the inclined side wall of the isolation structure 50 to the pixel opening 21 surrounded by the isolation structure 50 and the first spacing a1 from the side wall of the isolation structure 50 extending in the second direction to the pixel opening 21 surrounded by the isolation structure 50 is greater than or equal to 0.75 μm; and/or a difference between a second spacing a2 from the inclined side wall of the isolation structure 50 to the pixel opening 21 surrounded by the isolation structure 50 and the second spacing a2 from the side wall of the isolation structure 50 extending in the first direction to the pixel opening 21 surrounded by the isolation structure 50 is greater than or equal to 0.75 μm.

As shown in FIG. 8, in a direction parallel to the substrate 10, when a vertical spacing d between the side wall of the isolation structure 50 and the pixel opening 21 surrounded by the isolation structure 50 is fixed, a spacing a1′, in the first direction X, between the inclined side wall of each isolation structure 50 and the respective pixel opening 21 surrounded by and adjacent to the isolation structure 50 is greater than a spacing d between the side wall of the isolation structure 50 extending along the second direction Y and the respective pixel opening 21 surrounded by and adjacent to the isolation structure 50. That is, a1′>d. In addition, a spacing a2′, in the second direction Y, between the inclined side wall of each isolation structure 50 and the respective pixel opening 21 surrounded by and adjacent to the isolation structure 50 is greater than a spacing d between the side wall of the isolation structure 50 extending along the first direction X and the respective pixel opening 21 surrounded by and adjacent to the isolation structure 50. That is, a2′>d.

Therefore, in the present embodiment, a difference between the first spacing a1 (i.e., a1′) from the inclined side wall of the isolation structure 50 to the pixel opening 21 surrounded by the isolation structure 50 and the first spacing a1 from the side wall of the isolation structure 50 extending in the second direction to the pixel opening 21 surrounded by the isolation structure 50 is adjusted; and/or a difference between the first spacing a2 (i.e., a2′) from the inclined side wall of the isolation structure 50 to the pixel opening 21 surrounded by the isolation structure 50 and the second spacing a2 from the side wall of the isolation structure 50 extending in the first direction to the pixel opening 21 surrounded by the isolation structure 50 is adjusted. In this way, the spacing between the isolation structure 50 and the surrounded pixel opening 21 is adjusted, such that the pixel opening ratio is increased.

It is understood that, on the basis of the display panel in the first embodiment, in the present embodiment, the difference between the spacing, in the first direction X or in the second direction Y, from the inclined side wall of the isolation structure 50 to the pixel opening 21 surrounded by the isolation structure 50 and the spacing from the remaining side wall in the isolation structure 50, other than the inclined side wall, to the pixel opening 21 surrounded by the isolation structure 50 is taken into account, such that the pixel opening ratio is increased.

In other embodiments, the sub-pixels 30 may be in other shapes, and the sub-pixels 30 may also be arranged in other manners. The arrangement of the sub-pixels 30 in the present disclosure include, but are not limited to, the above arrangements.

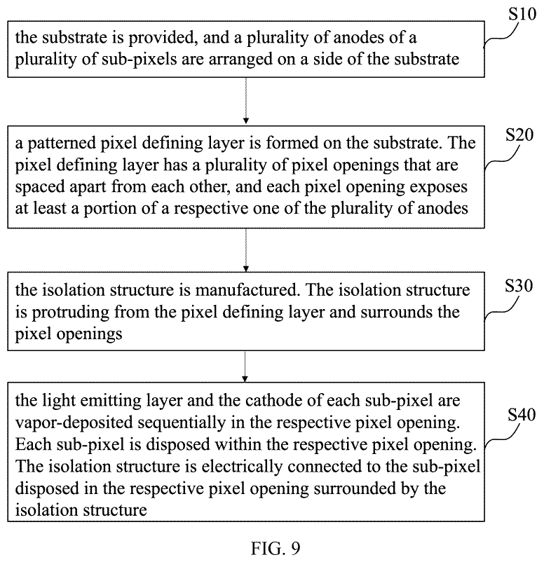

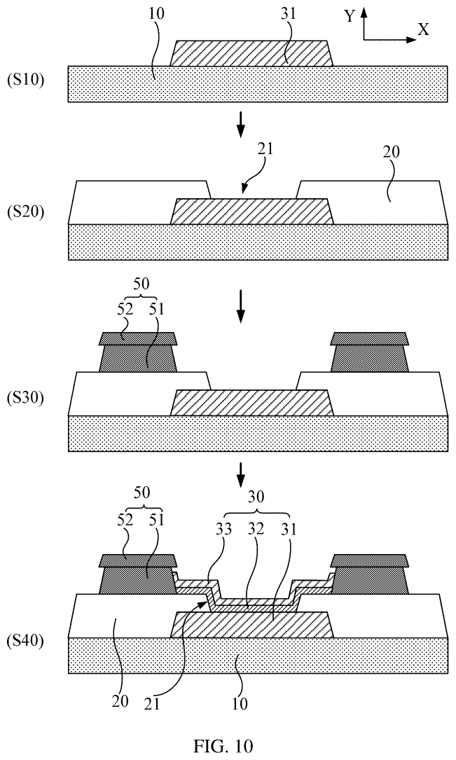

As shown in FIG. 9 and FIG. 10, FIG. 9 is a flow chart of a method of manufacturing the display panel according to an embodiment of the present disclosure; and FIG. 10 is a structural schematic view of structures corresponding to operations S10 to S40 in FIG. 9.

The present disclosure provides the method of manufacturing the display panel as described in the above.

The method of manufacturing the display panel includes following operations.

In an operation S10, the substrate is provided, and a plurality of anodes of a plurality of sub-pixels are arranged on a side of the substrate.

Specifically, the substrate 10 is provided, the side of the substrate 10 is patterned to form the plurality of anodes that are spaced apart from each other.

Methods for manufacturing the substrate 10 and the anodes 31 are not limited herein and can be determined according to demands.

In an operation S20, a patterned pixel defining layer is formed on the substrate. The pixel defining layer has a plurality of pixel openings that are spaced apart from each other, and each pixel opening exposes at least a portion of a respective one of the plurality of anodes.

The pixel defining layer 20 is formed on a side of the substrate 10 facing the anodes 31, and the pixel defining layer 20 is patterned to enable the pixel defining layer 20 to have the plurality of pixel openings 21 that are spaced apart from each other. The pixel openings 21 expose at least a portion of the anode 31.

In the present embodiment, the pixel openings 21 expose a portion of the anode 31.

In an operation S30, the isolation structure is manufactured. The isolation structure is protruding from the pixel defining layer and surrounds the pixel openings.

Specifically, the isolation structure 50 is formed on an upper surface of the pixel defining layer 20, such that the isolation structure 50 is protruding from the pixel defining layer 20 and surrounds the pixel openings 21.

In an embodiment, in the direction perpendicular to the substrate 10, the distance between the upper surface of the anode 31 and the upper surface of the isolation structure 50 is 1.3 μm to 2 μm.

Detailed structures of the isolation structure 50 will not be described herein, which may be referred to the above description.

In an operation S40, the light emitting layer and the cathode of each sub-pixel are vapor-deposited sequentially in the respective pixel opening. Each sub-pixel is disposed within the respective pixel opening. The isolation structure is electrically connected to the sub-pixel disposed in the respective pixel opening surrounded by the isolation structure.

Specifically, light emitting layers 32 and cathodes 33 of sub-pixels 30 of the same color are sequentially vapor-deposited in the respective pixel openings 21. Each sub-pixel 30 is disposed within the respective pixel opening 21. The isolation structure 50 is electrically connected to the sub-pixel 30 disposed in the respective pixel opening 21 surrounded by the isolation structure 50. The cathode 33 of the sub-pixel 30 extends out of the pixel opening 21 to be in contact with the conductive portion 51 of the isolation structure 50 to achieve the electrical connection between the sub-pixel 30 and the isolation structure 50.

The difference between the vapor-deposition angle θ2 (see FIG. 4) of the vapor-deposition material forming the light-emitting layer 32 or the cathode 33 in the second direction Y and the vapor-deposition angle θ1 (see FIG. 3) of the vapor-deposition material in the first direction X is greater than 10 degrees and less than 40 degrees. The first direction X and the second direction Y are perpendicular to each other and are parallel to the substrate 10.

Methods of the vapor-depositing the sub-pixels 30 are not limited herein and may be determined according to demands, as long as it is ensured that, when vapor-depositing the sub-pixels 30 of the same color, the difference between the vapor-deposition angle θ2 of the vapor-deposition material forming the light-emitting layer 32 or the cathode 33 in the second direction Y and the vapor-deposition angle θ1 of the vapor-deposition material in the first direction X is greater than 10 degrees and is less than 40 degrees.

In an embodiment, the operation S40 of sequentially vapor-depositing the light emitting layer and the cathode of the sub-pixel in the pixel opening, specifically includes following operations.

In an operation S41, the cathode and the light emitting layer of the sub-pixel are sequentially vapor-deposited on the upper surface of the anode by the vapor-deposition source. When vapor-depositing the cathode or the light emitting layer, the difference between the vapor-deposition angle, in the second direction, of the vapor-deposition material ejected from the vapor-deposition source and the vapor-deposition angle of the vapor-deposition material in the first direction is greater than 15 degrees and less than 30 degrees.

Specifically, the cathode 33 and the light-emitting layer 32 of the sub-pixel 30 are vapor-deposited on the upper surface of the anode 31 sequentially by the vapor-deposition source. When vapor-depositing the cathode 33 or the light-emitting layer 32, the difference between the vapor-deposition angle θ2 of the vapor-deposition material ejected from the vapor-deposition source in the second direction Y and the vapor-deposition angle θ1 of the vapor-deposition material in the first direction X is greater than 15 degrees and less than 30 degrees.

The first direction X is the moving direction of the vapor-deposition source, and the second direction Y is the longer-side direction of the vapor-deposition source.

To be noted that, the structural schematic views in the present disclosure are illustrated by taking vapor-depositing one sub-pixel 30 as an example. It is understood that, on the basis of the method of manufacturing the display panel in the art, in the method of manufacturing the display panel of the present disclosure, the difference between the vapor-deposition angle θ2 of the vapor-deposition material ejected from the vapor-deposition source in the second direction Y and the vapor-deposition angle θ1 of the vapor-deposition material in the first direction X is adjusted, and the difference between spacings, in different directions (i.e., the second direction Y and the first direction X) from the isolation structure 50 to the pixel opening 21 surrounded by and adjacent to the isolation structure 50 (referred to the above description, which will not be repeated herein) is adjusted, such that the pixel opening ratio is increased.

In the above embodiments, description of various embodiments has respective focuses, and a part that is not described in detail in one embodiment may be referred to the relevant description in other embodiments.

The above shows only embodiments of the present disclosure and is not intended to limit the scope of the present disclosure. Any equivalent structure or equivalent process transformation performed based on the contents of the specification and the accompanying drawings of the present disclosure, applied directly or indirectly in other related fields, shall be all equivalently included in the scope of the present disclosure.

What is claimed is:

1. A display panel, comprising:
a substrate;
a pixel defining layer, arranged on a side of the substrate and having a plurality of pixel openings that are spaced apart from each other;
a plurality of sub-pixels, wherein each of the plurality of sub-pixels is arranged in a respective one of the plurality of pixel openings; each of the plurality of sub-pixels comprises an anode, a light emitting layer and a cathode that are arranged sequentially in a direction away from the substrate;
an isolation structure, protruding from the pixel defining layer and surrounding at least one of the plurality of pixel openings; wherein, the isolation structure is electrically connected to a respective one of the plurality of sub-pixels arranged in the respective pixel opening surrounded by the isolation structure;
wherein, the light emitting layer and the cathode of the sub-pixel are vapor-deposited sequentially on an upper surface of the anode; a difference between a vapor-deposition angle of a vapor-deposition material forming the light emitting layer or the cathode in a second direction and a vapor-deposition angle of the vapor-deposition material in a first direction is greater than 10 degrees and less than 40 degrees; and the first and the second directions are perpendicular to each other and are parallel to the substrate.

2. The display panel according to claim 1, wherein, a pointing direction is from an edge of an upper surface of the isolation structure pointing towards an edge of an end of the respective pixel opening away from the substrate, wherein the respective pixel opening is surrounded by and adjacent to the isolation structure, and the vapor-deposition angle of the vapor-deposition material is an angle between the pointing direction and a direction perpendicular to the substrate;
the light emitting layer and the cathode of the sub-pixel are sequentially vapor-deposited on the upper surface of the anode by a vapor-deposition source, the first direction is a moving direction of the vapor-deposition source, and the second direction is a longer-side direction of the vapor-deposition source;
the difference between the vapor-deposition angle of the vapor-deposition material in the second direction and the vapor-deposition angle of the same vapor-deposition material in the first direction is greater than 15 degrees and less than 30 degrees.

3. The display panel according to claim 1, wherein, in a direction perpendicular to the substrate, a distance between the upper surface of the anode and an upper surface of the isolation structure is 1.3 μm to 2 μm.

4. The display panel according to claim 3, wherein, in the first direction, a spacing between an edge of the isolation structure to an edge of an end of the respective pixel opening away from the substrate is a first spacing, wherein the respective pixel opening is surrounded by and adjacent to the isolation structure, and a half of a width of a side wall of the isolation structure is a first width;
in the second direction, a spacing between the edge of the isolation structure to the edge of the respective pixel opening away from the substrate is a second spacing, wherein the respective pixel opening is surrounded by and adjacent to the isolation structure, and a half of a width of the side wall of the isolation structure is a second width;
a difference between the second spacing and the first spacing is greater than or equal to 0.75 μm.

5. The display panel according to claim 3, wherein, in the first direction, a spacing between an edge of the isolation structure to an edge of an end of the respective pixel opening away from the substrate is a first spacing, wherein the respective pixel opening is surrounded by and adjacent to the isolation structure, and a half of a width of a side wall of the isolation structure is a first width;
in the second direction, a spacing between the edge of the isolation structure to the edge of the respective pixel opening away from the substrate is a second spacing, wherein the respective pixel opening is surrounded by and adjacent to the isolation structure, and a half of a width of the side wall of the isolation structure is a second width;
an absolute difference value between the first width and the second width is greater than or equal to 0.75 μm.

6. The display panel according to claim 4, wherein, in a direction parallel to the substrate, a shape of a region surrounded by the isolation structure is a similar figure to a shape of the respective sub-pixel;
the sub-pixel comprises a side extending along the first direction and a side extending along the second direction.

7. The display panel according to claim 4, wherein,
in a direction parallel to the substrate, a shape of a region surrounded by the isolation structure is a similar figure to a shape of the respective sub-pixel;
each of the plurality of sub-pixels comprises at least an inclined side, each of a portion of the plurality of sub-pixels further comprises: a side extending along the first direction and/or a side extending along the second direction; the extending direction of the inclined side, the first direction, and the second direction are located in a same plane; an angle between the extending direction of the inclined side and the first direction is 30 degrees to 60 degrees, or an angle between the extending direction of the inclined side and the second direction is 30 degrees to 60 degrees.

8. The display panel according to claim 6, wherein one isolation structure surrounds one pixel opening; the sub-pixel comprises at least the inclined side, the isolation structure has an inclined side wall parallel to the inclined side of the sub-pixel; a difference between the first spacing from the inclined side wall of the isolation structure to the pixel opening surrounded by the isolation structure and the first spacing from a side wall of the isolation structure extending in the second direction to the pixel opening surrounded by the isolation structure is greater than or equal to 0.75 μm.

9. The display panel according to claim 6, wherein one isolation structure surrounds one pixel opening; the sub-pixel comprises at least the inclined side, the isolation structure has an inclined side wall parallel to the inclined side of the sub-pixel; a difference between the second spacing from the inclined side wall of the isolation structure to the pixel opening surrounded by the isolation structure and the second spacing from a side wall of the isolation structure extending in the first direction to the pixel opening surrounded by the isolation structure is greater than or equal to 0.75 μm.

10. The display panel according to claim 9, wherein, the display panel further comprises a plurality of pixel units, each of the plurality of pixel units comprises sub-pixels three different colors; and the sub-pixels of the three different colors are a first sub-pixel, a second sub-pixel and a third sub-pixel; for every two adjacent sub-pixels of the sub-pixels of the three different colors, each one of the two adjacent sub-pixels has a side disposed near the other one of the two adjacent sub-pixels, and the closely-disposed sides of the two adjacent sub-pixels are parallel to each other.

11. The display panel according to claim 10, wherein,
each of the first sub-pixel and the second sub-pixel is octagonal, and each of the octagonal first sub-pixel and the octagonal second sub-pixel is centrally symmetric, the third sub-pixel is parallelogram; the first sub-pixel and the second sub-pixel are arranged sequentially and alternately in the first direction and are arranged sequentially alternately in the second direction; four third sub-pixels surround one first sub-pixel and are arranged symmetrically along the first direction and the second direction; four third sub-pixels surround one second sub-pixel and are symmetrically arranged along the first direction and the second direction.

12. The display panel according to claim 11, wherein, when the first sub-pixel and the second sub-pixel have a same shape and a same size, a plurality of first sub-pixels are repeatedly arranged in the second direction, and a plurality of second sub-pixels are repeatedly arranged in the second direction.

13. The display panel according to claim 1, wherein, the isolation structure comprises a conductive portion and an insulation portion arranged on an upper surface of the conductive portion; the insulation portion shields the conductive portion and extends out of the conductive portion in a direction parallel to the substrate; the conductive portion is electrically connected to the cathode of the respective sub-pixel surrounded by the isolation structure.

14. The display panel according to claim 13, wherein, an area of an orthographic projection of the insulation portion on the substrate is greater than an area of an orthographic projection of the conductive portion on the substrate.

15. The display panel according to claim 14, wherein, the orthographic projection of the insulation portion on the substrate covers the orthographic projection of the conductive portion on the substrate.

16. The display panel according to claim 13, wherein, an edge of the insulation portion is configured to adjust the vapor-deposition angle.

17. A method of manufacturing the display panel according to claim 1, the method comprising:
providing a substrate and preparing a plurality of anodes of the plurality of sub-pixels on a side of the substrate;
forming a patterned pixel defining layer on the substrate, wherein, the pixel defining layer has the plurality of pixel openings that are spaced apart from each other, each of the plurality of pixel openings exposes at least a portion of a respective one of the plurality of anodes;
preparing the isolation structure, wherein, the isolation structure is protruding from the pixel defining layer and surrounds the respective one of the plurality of pixel openings;
sequentially vapor-depositing the light emitting layer of each sub-pixel and the cathode of each sub-pixel in the respective pixel opening; wherein, each of the plurality of sub-pixels is received in a respective one of the plurality of pixel openings; the isolation structure is electrically connected to the respective sub-pixel arranged in the respective pixel opening surrounded by the isolation structure;
wherein, the difference between the vapor-deposition angle of the vapor-deposition material forming the light emitting layer or the cathode in the second direction and the vapor-deposition angle of the vapor-deposition material in the first direction is greater than 10 degrees and less than 40 degrees; wherein the first direction and the second direction are perpendicular to each other and are parallel to the substrate.

18. The method according to claim 17, wherein, the sequentially vapor-depositing the light emitting layer of each sub-pixel and the cathode of each sub-pixel in the respective pixel opening, comprises:
sequentially vapor-depositing the cathode and the light emitting layer of the sub-pixel on the upper surface of the anode by the vapor-deposition source; and when vapor-depositing the cathode or the light emitting layer, the difference between the vapor-deposition angle of the vapor-deposition material ejected from the vapor-deposition source in the second direction and the vapor-deposition angle of the vapor-deposition material in the first direction is greater than 15 degrees and less than 30 degrees.

19. The method according to claim 18, wherein, a pointing direction is from an edge of an upper surface of the isolation structure pointing towards an edge of an end of the respective pixel opening away from the substrate, wherein the respective pixel opening is surrounded by and adjacent to the isolation structure, and the vapor-deposition angle of the vapor-deposition material is an angle between the pointing direction and a direction perpendicular to the substrate.

20. The method according to claim 17, wherein, in a direction perpendicular to the substrate, a distance between an upper surface of the anode and an upper surface of the isolation structure is 1.3 μm to 2 μm.
